(19) United States
(12) Patent Application Publication
(10) Pub. No.: US 2025/0159990 A1
(43) Pub. Date: May 15, 2025

(54) DISPLAY PANEL AND DISPLAY DEVICE

(71) Applicant: Wuhan China Star Optoelectronics Technology Co., Ltd., Wuhan (CN)

(72) Inventors: Liwang LIU, Wuhan (CN); Zemin HU, Wuhan (CN)

(73) Assignee: Wuhan China Star Optoelectronics Technology Co., Ltd., Wuhan (CN)

(21) Appl. No.: 18/412,658

(22) Filed: Jan. 15, 2024

Related U.S. Application Data
(63) Continuation of application No. PCT/CN2023/135140, filed on Nov. 29, 2023.

(30) Foreign Application Priority Data
Nov. 10, 2023 (CN) 202311513373.4

(51) Int. Cl. H01L 27/12

(52) U.S. Cl. CPC H10D 86/60; H10D 86/423; H10D 86/441

(57) ABSTRACT

In a display area, a display panel includes a metal oxide semiconductor layer disposed between a substrate and a first metal layer. The metal oxide semiconductor layer includes multiple transparent active layers. Two first electrode conductor portions respectively in any two adjacent ones of the transparent active layers are staggered.

### CROSS-REFERENCE TO RELATED APPLICATIONS

This application is a Continuation of PCT Patent Application No. PCT/CN2023/135140 having International filing date of Nov. 29, 2023, which claims the benefit of priority of China Patent Application No. 202311513373.4 filed on Nov. 10, 2023. The contents of the above applications are all incorporated by reference as if fully set forth herein in their entirety.

### FIELD

The present disclosure relates to display technologies, and more particularly, to a display panel and a display device.

### BACKGROUND

With the development of display technology, consumer electronic products such as a mobile phone, a television, a personal digital assistant, a digital camera, a notebook computer, a desktop computer, a Virtual Reality (VR) display device, and an Augmented Reality (AR) display device, which rely on a display function of a display panel, are constantly emerging. Rise of a concept of “meta-universe” also causes a VR/AR display device to be widely concerned by consumers and has a broad market application prospect.

A VR/AR display device is a near-eye display device and has a high requirement for the resolution of the display panel therein. In a conventional pixel design architecture, the resolution of a display panel in a VR/AR display device can only reach 1000-1500 pixels per inch (PPI), and still cannot meet a user requirement. If the resolution is further improved, the relevant safety distance cannot be ensured due to limited space for layout, thereby reducing a product yield of display panels.

Therefore, there is a need to improve a product yield of display panels while ensuring high pixel resolution of each display panel.

### SUMMARY

A display panel according to one or more embodiments of the present disclosure has a display area, a part of the display panel in the display area including: a substrate; a first metal layer disposed on a side of the substrate, the first metal layer including multiple data lines arranged at intervals in a first direction; a metal oxide semiconductor layer disposed between the substrate and the first metal layer, the metal oxide semiconductor layer including multiple transparent active layers, each of the transparent active layers including a first electrode conductor portion, and an orthographic projection of the first electrode conductor portion on the substrate being between two adjacent ones of the data lines; and a transparent conductive layer disposed on a side of the first metal layer away from the metal oxide semiconductor layer, the transparent conductive layer including multiple first electrodes, the first electrode conductor portion being electrically connected to one of the first electrodes by a via hole connection, respective first electrode conductor portions in any two adjacent ones of the transparent active layers in the first direction being staggered.

A display device according to one or more embodiments of the present disclosure includes a housing and any one of above-mentioned display panels, the housing having an accommodation space in which the display panel is disposed.

### BRIEF DESCRIPTION OF THE DRAWINGS

FIG. 1 is a schematic plan view of multiple layers of a display panel in a display area according to Example 1 of the present disclosure.

FIG. 2 is a schematic cross-sectional view of the multiple layers taken along line AA′ in FIG. 1 according to Example 1 of the present disclosure.

FIG. 3 is a schematic plan view of a first metal layer in the display area according to Example 1 of the present disclosure.

FIG. 4 is a schematic plan view of a metal oxide semiconductor layer in the display area according to Example 1 of the present disclosure.

FIG. 5 is a schematic plan view of a transparent conductive layer in the display area according to Example 1 of the present disclosure.

FIG. 6 is a schematic plan view of a second metal layer in the display area according to Example 1 of the present disclosure.

FIG. 7 is a schematic plan view of multiple layers of a display panel in a display area according to Example 2 of the present disclosure.

FIG. 8 is a schematic plan view of a metal oxide semiconductor layer in the display area according to Example 2 of the present disclosure.

FIG. 9 is a block diagram of a display device according to some embodiments of the present disclosure.

### DETAILED DESCRIPTION

A display panel according to one or more embodiments of the present disclosure has a display area, a part of the display panel in the display area including: a substrate; a first metal layer disposed on a side of the substrate, the first metal layer including multiple data lines arranged at intervals in a first direction; a metal oxide semiconductor layer disposed between the substrate and the first metal layer, the metal oxide semiconductor layer including multiple transparent active layers, each of the transparent active layers comprising a first electrode conductor portion, and an orthographic projection of the first electrode conductor portion on the substrate being between two adjacent ones of the data lines; and a transparent conductive layer disposed on a side of the first metal layer away from the metal oxide semiconductor layer, the transparent conductive layer including multiple first electrodes, the first electrode conductor portion being electrically connected to one of the first electrodes by a via hole connection, respective first electrode conductor portions in any two adjacent ones of the transparent active layers in the first direction being staggered.

Optionally, the display panel in the display area further includes: a second metal layer disposed between the metal oxide semiconductor layer and the first metal layer, the second metal layer including multiple gate lines arranged at intervals in a second direction, and the first direction intersecting with the second direction, one of the respective first electrode conductor portions in any two adjacent ones of the transparent active layers in the first direction is disposed on a side of one of the gate lines, and an other of the respective first electrode conductor portions in any two adjacent ones of the transparent active layers in the first direction is disposed on an other side of the one of the gate lines.

Optionally, a distance between an end of one of the respective first electrode conductor portions away from the one of the gate lines and the one of the gate lines is a first distance, and a distance between two adjacent gate lines is a second distance, and the first distance is less than half of the second distance.

Optionally, each of the transparent active layers further includes a channel and a second electrode conductor portion, the first electrode conductor portion and the second electrode conductor portion being provided on two sides of the channel, an orthographic projection of the channel on the substrate overlaps an orthographic projection of the one of the gate lines on the substrate, an orthographic projection of the second electrode conductor portion on the substrate overlaps an orthographic projection of one of the data lines on the substrate, and the second electrode conductor portion is electrically connected to the one of the data lines by a via hole connection.

Optionally, the second electrode conductor portion in the transparent active layer is electrically connected to the one of the data line through a second electrode connection hole, respective second electrode conductor portions in the plurality of the transparent active layers are spaced, and there is a one-to-one correspondence between the second electrode conductor portion and the second electrode connection hole.

Optionally, the second electrode conductor portion in the transparent active layer is electrically connected to the one of the data lines through a second electrode connection hole, respective second electrode conductor portions of at least two adjacent ones of the transparent active layers are joined, and the second electrode connection hole corresponds to each of two of the second electrode conductor portions that are joined.

Optionally, two transparent active layers respectively corresponding to the two of the second electrode conductor portions that are joined are in an integrated structure, and the two transparent active layers are disposed axisymmetrically.

Optionally, the first electrode conductor portion is electrically connected to one of the first electrodes through a first electrode connection hole, each of the first electrodes comprises a first portion and a second portion, the first portion covering at least part of the channel, the second portion covering the first electrode connection hole, and a maximum width of the second portion in the first direction being greater than a maximum width of the first portion in the first direction.

Optionally, the display panel in the display area includes multiple metal oxide thin film transistors, each of the metal oxide thin film transistors includes one of the transparent active layers, a first gate, one of the first electrodes, and a second electrode, the second electrode is electrically connected to the second electrode conductor portion by a via hole connection, the second electrode is part of one of the data lines, and the first gate is part of one of the gate lines.

Optionally, the display panel in the display area further includes a third metal layer disposed on a side of the metal oxide semiconductor layer facing the substrate, the metal oxide thin film transistor includes a second gate, the second gate is disposed on the third metal layer, and an orthographic projection of the second gate on the substrate overlaps the orthographic projection of the channel in the transparent active layer on the substrate.

A display device according to one or more embodiments of the present disclosure includes a housing and any one of above-mentioned display panels, the housing having an accommodation space in which the display panel is disposed.

A display panel according to one or more embodiments of the present disclosure has a display area, a part of the display panel in the display area including: a substrate; a first metal layer disposed on a side of the substrate, the first metal layer including multiple data lines arranged at intervals in a first direction; a metal oxide semiconductor layer disposed between the substrate and the first metal layer, the metal oxide semiconductor layer including multiple transparent active layers, each of the transparent active layers comprising a first electrode conductor portion, and an orthographic projection of the first electrode conductor portion on the substrate being between two adjacent ones of the data lines; and a transparent conductive layer disposed on a side of the first metal layer away from the metal oxide semiconductor layer, the transparent conductive layer including multiple first electrodes, the first electrode conductor portion being electrically connected to one of the first electrodes by a via hole connection, respective first electrode conductor portions in any two adjacent ones of the transparent active layers in the first direction being staggered. In the display panel according to one or more embodiments of the present disclosure, two first electrode conductor portions are staggered so that the product yield of the display panel can be improved while ensuring high resolution of the display panel.

In the following, the technical solutions in one or more embodiments of the present disclosure will be clearly and completely described with reference to the accompanying drawings in one or more embodiments of the present disclosure. It will be apparent that the described embodiments are merely a part of the embodiments of the present disclosure, rather than all the embodiments. Based on one or more embodiments in the present disclosure, all other one or more embodiments obtained by those skilled in the art without involving any inventive effort are within the scope of the present disclosure. Furthermore, it is to be understood that the specific embodiments described herein are for purposes of illustration and explanation only and are not intended to limit the present disclosure. In the present disclosure, if not stated to the contrary, positional terms used such as “up” and “down” usually refer to up and down in actual use or working state of a device, specifically in a surface direction in the accompanying drawing. While terms such as “in” and “out” are in respect to an outline of a device.

The following disclosure provides many different embodiments or examples for implementing the different structures of the present disclosure. In order to simplify the disclosure of the present disclosure, components and arrangements of specific examples are described below. Of course, they are merely examples and are not intended to limit the present disclosure. In addition, the present disclosure may repeat reference numerals and/or reference letters in different examples. Such a repetition is for the purpose of simplicity and clarity, without indicating a relationship between various embodiments and/or arrangements discussed. In addition, the present disclosure provides examples of various specific processes and materials, but those skilled in the art will recognize application of other processes and/or use of other materials. In the following detailed description, it is to be noted that an order described in one or more embodiments is not intended to limit a preferred order of one or more embodiments.

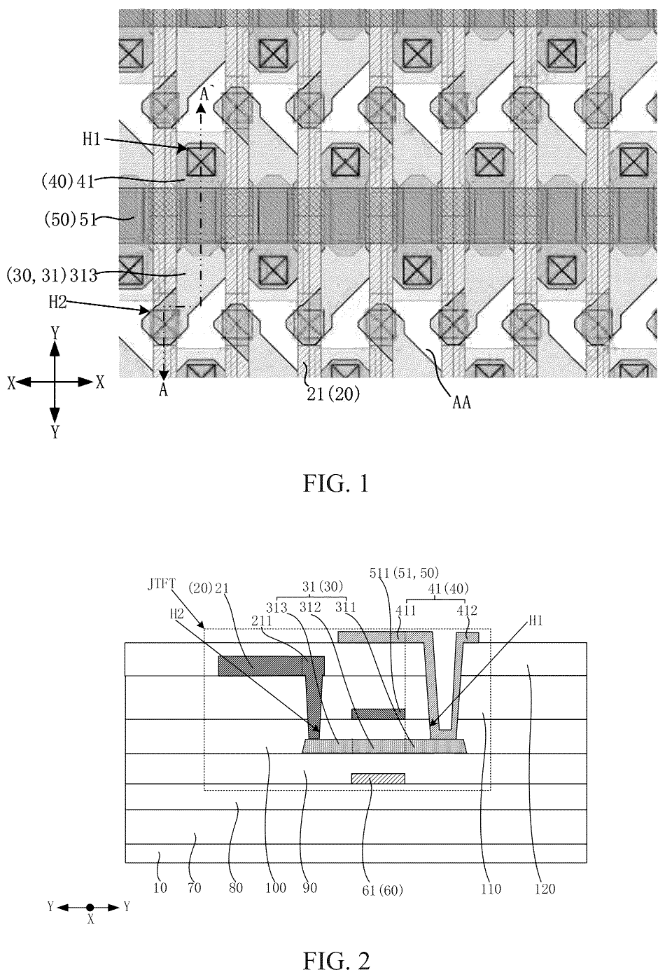

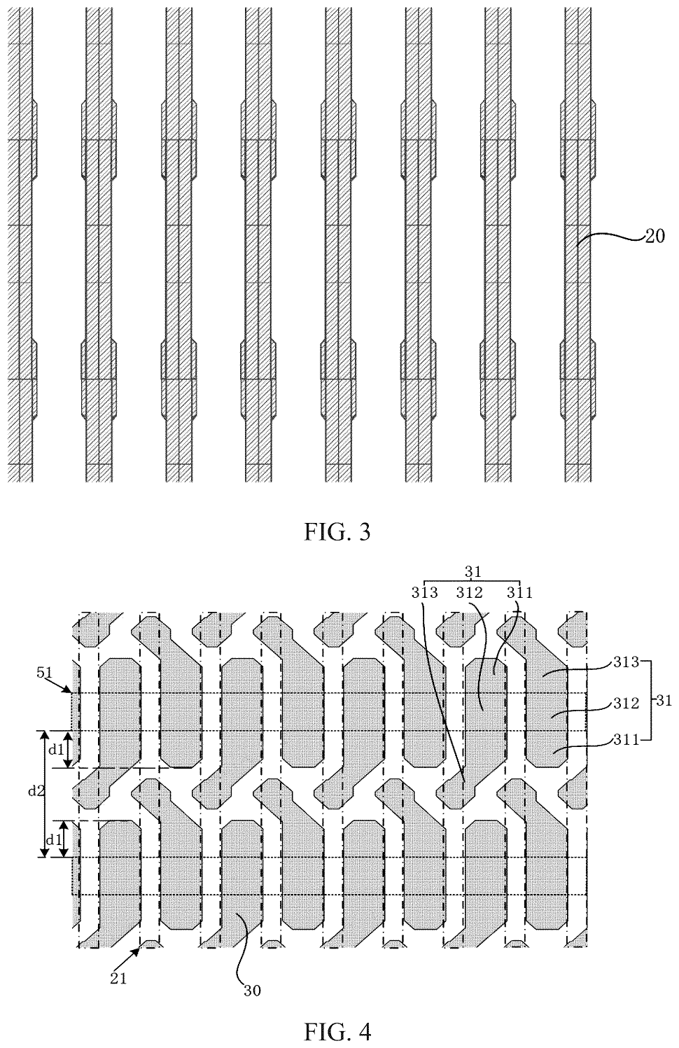

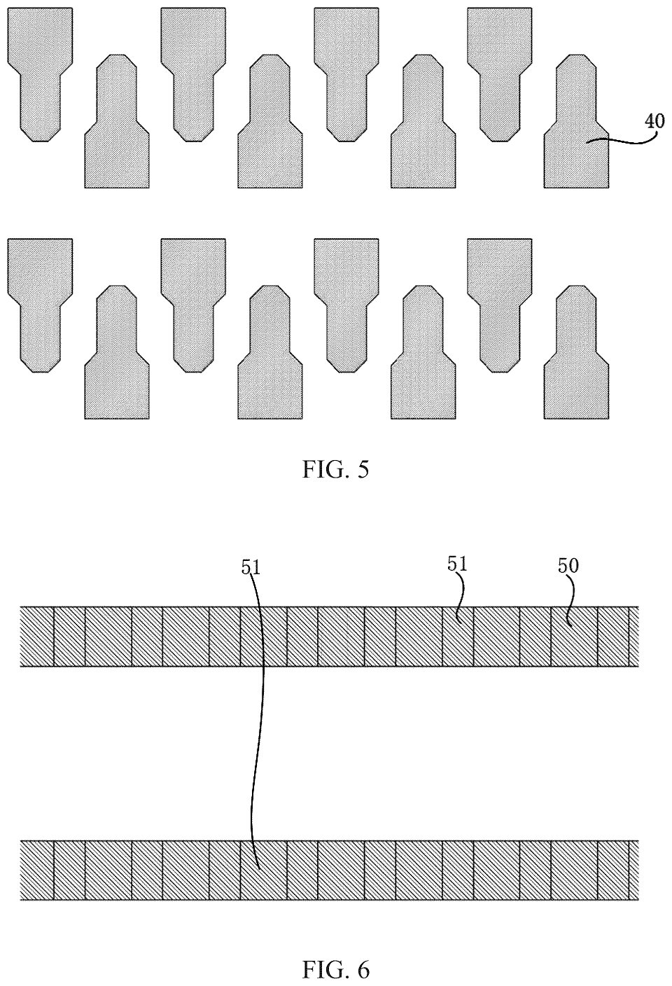

FIG. 1 is a plan view of multiple layers of a display panel in a display area according to Example 1 of the present disclosure. FIG. 2 is a schematic cross-sectional view taken along line AA′ in FIG. 1 according to Example 1 of the present disclosure. FIG. 3 is a schematic plan view of a first metal layer in a display area according to Example 1 of the present disclosure. FIG. 4 is a schematic plan view of a metal oxide semiconductor layer in a display area according to Example 1 of the present disclosure. FIG. 5 is a schematic plan view of a transparent conductive layer of a display area according to Example 1 of the present disclosure. As shown in FIGS. 1 to 5, in a first aspect, a display panel according to Example 1 of the present disclosure may be applied to a VR-type display device with a high-resolution display requirement. The display panel may be a liquid crystal display panel.

Specifically, the display panel has a display area AA. A part of the display panel in the display area AA includes a substrate 10; a first metal layer 20 disposed on a side of the substrate 10, the first metal layer including multiple data lines arranged at intervals in a first direction X; a metal oxide semiconductor layer 30 disposed between the substrate 10 and the first metal layer 20, the metal oxide semiconductor layer including multiple transparent active layers 31, the transparent active layers including respective first electrode conductor portions 311, an orthographic projection of each of the first electrode conductor portions 311 on the substrate 10 being between two adjacent ones of the data lines 21; a transparent conductive layer 40 disposed on a side of the first metal layer 20 away from the metal oxide semiconductor layer 30, the transparent conductive layer 40 including multiple first electrodes 41, each of the first electrodes 41 being electrically connected to one of the first electrode conductor portions 311 through a via hole. Respective first electrode conductor portions 311 in any two adjacent ones of the transparent active layers 31 in the first direction X are staggered.

In the display panel according to one or more embodiments of the present disclosure, since the metal oxide semiconductor layer 30 has light transmittance, the transparent active layer 31 may be formed by using the metal oxide semiconductor layer 30 having light transmittance. The first electrode conductor portion 311 in the transparent active layer 31 is disposed between two adjacent data lines 21, so that an area in which the first electrode conductor portion 311 is disposed can be used as a pixel area in the display panel. Thus space utilization rate and opening rate of the display area AA is improved, and the number of pixel areas that can be disposed in the limited display area AA is increased, thereby improving the resolution of the display panel. Illustratively, the display panel is a liquid crystal display panel. When the first electrode conductor portion 311 is disposed at a position between two adjacent data lines 21, since the first electrode conductor portion 311 has light transmittance, the first electrode conductor portion 311 does not block light emitted by backlight in the liquid crystal display panel. Thus, an area in which the first electrode conductor portion 311 is disposed has a prerequisite for being used as a pixel area.

The transparent active layer 31 is a part of the metal oxide thin film transistor JTFT in the display area AA. As a driving element of the display panel, the metal oxide thin film transistor JTFT needs to supply a driving signal to a pixel electrode in the pixel area. In order to ensure normal transmission of the driving signal, the metal oxide thin film transistor JTFT also needs to include a first electrode 41 electrically connected to the first electrode conductor portion 311 and the pixel electrode, and the first electrode 41 is electrically connected to the first electrode conductor portion 311 through a via hole as an interconnecting structure. Therefore, inevitably, the first electrode conductor portion 311 and the first electrode 41 overlap in a direction perpendicular to the substrate 10 so as to facilitate arrangement of the via hole. As described above, a requirement exists for an area in which the first electrode conductor portion 311 is disposed to be used as a pixel region. Therefore, in order to ensure light transmittance of the area in which the first electrode conductor portion 311 is disposed, the first electrode 41 is formed using the transparent conductive layer 40 with light transmittance.

However, it is found that since the first electrode 41 is electrically connected to the first electrode conductor portion 311 by a via hole connection, in order to ensure the stability of the via connection, it is necessary to ensure a coverage the first electrode 41 to the via hole. Thus, a maximum width of the first electrode 41 corresponding to the via hole and the first electrode conductor portion 311 in the first direction X (that is, arrangement direction of the data lines 21) should be greater than a maximum width of the via hole in the first direction X, so that the maximum width of the first electrode 41 corresponding to the via hole and the first electrode conductor portion 311 in the first direction is greater. Generally, since each of the first electrodes 41 is arranged repeatedly in the first direction X in sequence, such an arrangement causes a small distance between two adjacent first electrodes 41 in the first direction X, thereby causing a safety problem, and greatly reducing the stability and yield of the display panel. According to one or more embodiments of the present disclosure, two first electrode conductor portions 311 respectively in any two adjacent transparent active layers 31 in the first direction X are staggered, so that the via holes respectively corresponding to the two first electrode conductor portions 311 in the two adjacent transparent active layers 31 in the first direction X are staggered, and portions of the first electrodes 41 respectively corresponding to the two first electrode conductor portions 311 in the two adjacent transparent active layers 31 in the first direction X are staggered, thereby preventing a safety problem caused by a too small distance between respective portions of the two adjacent first electrodes 41 in the first direction X which respectively cover the via holes, thereby enabling the display panel to achieve high resolution while improving the stability and yield of the display panel.

In one or more embodiments of the present disclosure, the display panel in the display area AA further includes a second metal layer 50 disposed between the metal oxide semiconductor layer 30 and the first metal layer 20. The second metal layer 50 includes multiple gate lines 51 arranged at intervals in a second direction Y. The first direction X intersects with the second direction Y. In any two adjacent transparent active layers 31 in the first direction X, one of the first electrode conductor portions 311 is provided on a side of the gate line 51 and another of the first electrode conductor portions 311 is provided on another side of the gate line 51.

In the display panel according to one or more embodiments of the present disclosure, multiple gate lines 51 arranged at intervals in the second direction Y intersect with multiple data lines 21 arranged at intervals in the first direction X, so that two adjacent data lines 21 and two adjacent gate lines 51 define a pixel area, thereby forming multiple pixel areas in array. That is, the gate line 51 disposed in the second metal layer 50 can space two adjacent pixel regions in the second direction Y. According to one or more embodiments of the present disclosure, in any two adjacent transparent active layers 31 in the first direction X, one of the first electrode conductor portions 311 is provided on a side of the gate line 51 and another of the first electrode conductor portions 311 is provided on another side of the gate line 51. Thus, in a layout design of the display, the one of the first electrode conductor portions 311 and the other of the first electrode conductor portions 311 can be positioned accurately based on the gate line 51, thereby ensuring that the two first electrode conductor portions 311 are staggered, making positions of subsequently forming via holes respectively corresponding to the first electrode conductor portions 311 more precise, and further improving production yield.

In one or more embodiments of the present disclosure, a distance between an end of the first electrode conductor portion 311 away from the gate line 51 and the gate line 51 is a first distance d1, and a distance between two adjacent gate lines 51 is a second distance d2. The first distance d1 is less than half of the second distance d2.

In the display panel according to one or more embodiments of the present disclosure, the two first electrode conductor portions 311 are respectively provided on two sides of the gate line 51 so as to be staggered. Accordingly, in an area between two adjacent gate lines 51, two first electrode conductor portions 311 are provided on two sides of one data line 21, respectively. According to one or more embodiments of the present disclosure, in order to prevent a problem that a distance between two first electrodes 41 respectively electrically connected to each of the two first electrode conductor portions 311 respectively on two sides of the data line 21 in the region between two adjacent gate lines 51 is too small, the distance between an end of the first electrode conductor portion 311 away from the gate line 51 and the gate line 51 is controlled. That is, according to one or more embodiments of the present disclosure, by making the distance between an end of the first electrode conductor portion 311 away from the gate line 51 and the gate line 51 less than half of the distance between two adjacent gate lines 51, the problem that the distance between two first electrodes 41 respectively electrically connected to each of the two first electrode conductor portions 311 respectively on two sides of the data line 21 in the region between two adjacent gate lines 51 is too small is prevented, thereby improving the safety and yield of the display panel. Optionally, a width of the data line 21 is a first width, and a difference between the second distance d2 and two first distances d1 is greater than or equal to the first width, so as to further improve the safety and yield of the display panel.

In one or more embodiments of the present disclosure, the transparent active layer 31 further includes a channel 312 and a second electrode conductor portion 313, The first electrode conductor portion 311 and the second electrode conductor portion 313 are respectively provided on two sides of the channel 312. An orthographic projection of the channel 312 on the substrate 10 overlaps an orthographic projection of the gate line 51 on the substrate 10, an orthographic projection of the second electrode conductor portion 313 on the substrate 10 overlaps an orthographic projection of the data line 21 on the substrate 10, and the second electrode conductor portion 313 is electrically connected to the data line 21 through a via hole.

In the display panel according to one or more embodiments of the present disclosure, the performance of the channel 312 of the transparent active layer 31 directly affects the device performance of the metal oxide thin film transistor JTFT, and the performance of the channel 312 is deteriorated due to light. According to one or more embodiments of the present disclosure, the orthographic projection of the channel 312 on the substrate 10 overlaps the orthographic projection of the gate line 51 on the substrate 10. Thus, on one hand, the channel 312 is disposed in an area covered by the gate line 51 in the display area AA, that is, the channel 312 is disposed in an area outside the pixel area in the display area AA, thereby preventing the channel 312 from occupying the space of the pixel area and improving the space utilization rate of the display area AA. On the other hand, external ambient light is blocked by using the opacity of the gate line 51, thereby ensuring the performance of the channel 312. In addition, in order to ensure that the driving signal in the data line 21 can be smoothly transmitted to the metal oxide thin film transistor JTFT, it is necessary to electrically connect the second electrode conductor portion 313 to the data line 21. According to one or more embodiments of the present disclosure, the orthographic projection of the channel 313 on the substrate 10 overlaps the orthographic projection of the data line 21 on the substrate 10, so that it is ensured that the second electrode conductor portion 313 can be electrically connected to the data line 21 through a via hole.

In one or more embodiments of the present disclosure, the second electrode conductor portion 313 in the transparent active layer 31 is electrically connected to the data line 21 through a second electrode connection hole H2. The second electrode conductor portion 313 in each of the transparent active layers 31 and the second electrode conductor portion 313 in another transparent active layer 31 are spaced, and there is a one-to-one correspondence between the second electrode conductor portion 313 and the second electrode connection hole H2.

In the display panel according to one or more embodiments of the present disclosure, since the second electrode conductor portion 313 in each of the transparent active layers 31 and the second electrode conductor portion 313 in another transparent active layer 31 are spaced, and there is a one-to-one correspondence between the second electrode conductor portion 313 and the second electrode connection hole H2, each second electrode conductor portion 313 is provided independently. Thus, the transparent active layer 31 can be provided in a same shape, thereby reducing difficulty of the layout design of the transparent active layer 31 and simplifying the manufacturing process.

In one or more embodiments of the present disclosure, the first electrode 41 is electrically connected to the first electrode conductor portion 311 through a first electrode connection hole H1. The first electrode 41 includes a first portion 411 and a second portion 412, the first portion 411 covers at least part of the channel 312, the second portion 412 covers the first electrode connection hole H1, and a maximum width of the second portion 412 in the first direction X is greater than a maximum width of the first portion 411 in the first direction X.

In the display panel according to one or more embodiments of the present disclosure, the first electrode 41 is electrically connected to the first electrode conductor portion 311 through the first electrode connection hole H1, and the second portion 412 of the first electrode 41 covers the first electrode connection hole H1. Therefore, the first electrode 41 needs to have a large width to ensure the stability of a via connection. Accordingly, when multiple second portions 412 are repeatedly arranged in the first direction X, there is likely a safety problem that a distance between the second portions 412 is too small. The second portion 412 of the first electrode 41 covers the first electrode connection hole H1, that is, the first electrode 41 is provided corresponding to the first electrode conductor portion 311. Thus, according to one or more embodiments of the present disclosure, in any two adjacent transparent active layers 31 in the first direction X, two first electrode conductor portions 311 are staggered, thereby improving the safety problem between the second portions 412 having a large width.

In addition, the first portion 411 of the first electrode 41 is configured to be electrically connected to the pixel electrode. For a design purpose, the first portion 411 needs to cover at least part of the channel 312, but this also makes it possible that respective first portions 411 of the two adjacent first electrodes 41 in the first direction X cannot be arranged in a staggered manner. Therefore, according to one or more embodiments of the present disclosure, the maximum width of the first portions 411 is less than the maximum width of the second portions 412, ensuring safety between the adjacent first electrodes 41 in the first direction X.

In one or more embodiments of the present disclosure, the display panel in the display area AA includes multiple metal oxide thin film transistors JTFT. The metal oxide thin film transistors JTFT includes the transparent active layer 31, a first gate electrode 511, the first electrode 41, and a second electrode 211. The second electrode 211 is electrically connected to the second electrode conductor portion 313 through a via hole. The second electrode 211 is a part of the data line 21 and the first gate electrode 511 is a part of the gate line 51.

In the display panel according to one or more embodiments of the present disclosure, the first electrode 41 is one of a source and a drain, the second electrode 211 is another of the source and the drain, and the transparent active layer 31, the first gate electrode 511, the first electrode 41, and the second electrode 211 are indispensable parts of the metal oxide thin film transistor JTFT. According to one or more embodiments of the present disclosure, by using the transparent active layer 31 and the first electrode 41 with transmittance, the opening rate of the display panel is greatly improved. Further, according to one or more embodiments of the present disclosure, by using the second electrode 211 as a part of the data line 21 and the first gate electrode 511 as a part of the gate line 51, a problem of complicated layout design caused by separate preparation of the first gate electrode 511 and the second electrode 211 can be prevented, and layout design area of the first gate electrode 511 and the second electrode 211 can be reduced as much as possible, thereby reducing the area of the light-opaque member in the metal oxide thin film transistor JTFT, thereby further improving the opening rate of the display panel.

In one or more embodiments of the present disclosure, pixel electrodes in the display panel are disposed on a side of the transparent conductive layer 40 away from the substrate 10, and the pixel electrodes may be arranged in one or more layers.

In one or more embodiments of the present disclosure, the display panel in the display area AA further includes a third metal layer 60 disposed on a side of the metal oxide semiconductor layer 30 facing the substrate 10. The metal oxide thin film transistor JTFT includes a second gate 61 disposed in the third metal layer 60. An orthographic projection of the second gate electrode 61 on the substrate 10 overlaps an orthographic projection of the channel 312 in the transparent active layer 31 on the substrate 10, so as to block the channel 312, thereby preventing a problem of deterioration of device performance due to the illumination of the channel 312 by the light emitted by the backlight source. Alternatively, the third metal layer 60 comprises a bottom gate line, and the second gate 61 is a part of the bottom gate line.

In one or more embodiments of the present disclosure, the display panel further includes a functional layer 70, a first gate insulating layer 80, a second gate insulating layer 90, a third gate insulating layer 100, a first interlayer dielectric layer 110, and a second interlayer dielectric layer 120. The functional layer 70 is disposed on a side of the substrate 10, and the functional layer 70 may be at least one of a buffer layer and a barrier layer. The first gate insulating layer 80 is disposed on a side of the functional layer 70 away from the substrate 10; The third metal layer 60 is disposed on a side of the first gate insulating layer 80 away from the functional layer 70. The second gate insulating layer 90 is disposed on a side of the third metal layer 60 away from the first gate insulating layer 80. The metal oxide semiconductor layer 30 is disposed on a side of the second gate insulating layer 90 away from the third metal layer 60. The third gate insulating layer 100 is disposed on a side of the metal oxide semiconductor layer 30 away from the second gate insulating layer 90. The second metal layer 50 is disposed on a side of the third gate insulating layer 100 away from the metal oxide semiconductor layer 30. The first interlayer dielectric layer 110 is disposed on a side of the second metal layer 50 away from the third gate insulating layer 100. The first metal layer 20 is disposed on a side of the first interlayer dielectric layer 110 away from the second metal layer 50. The second interlayer dielectric layer 120 is disposed on a side of the first metal layer 20 away from the first interlayer dielectric layer 110. The transparent conductive layer 40 is disposed on a side of the second interlayer dielectric layer 120 away from the first metal layer 20.

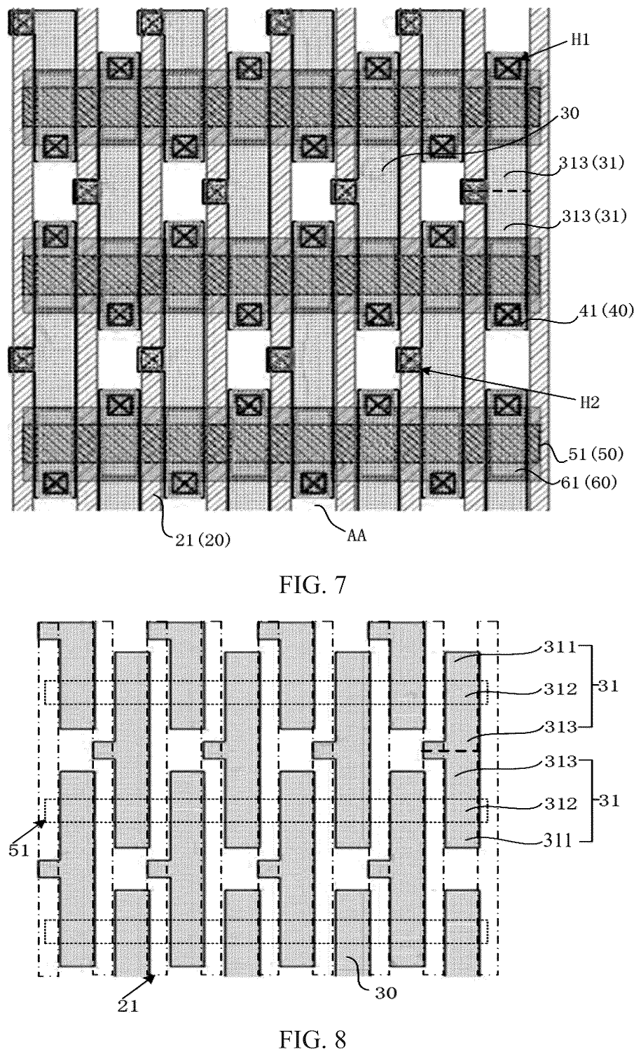

FIG. 7 is a plan view of multiple layers of a display panel in a display area according to Example 2 of the present disclosure. FIG. 8 is a schematic plan view of a metal oxide semiconductor layer in a display area according to Example 2 of the present disclosure. As shown in FIG. 2, FIG. 7 and FIG. 8, in a first aspect, according to Example 2 of the present disclosure, a display panel has a display area AA. A part of the display panel in the display area AA includes a substrate 10; a first metal layer 20 disposed on a side of the substrate 10, the first metal layer including multiple data lines arranged at intervals in a first direction X; a metal oxide semiconductor layer 30 disposed between the substrate 10 and the first metal layer 20, the metal oxide semiconductor layer including multiple transparent active layers 31, the transparent active layers including respective first electrode conductor portions 311, an orthographic projection of each of the first electrode conductor portions 311 on the substrate 10 being between two adjacent ones of the data lines 21; a transparent conductive layer 40 disposed on a side of the first metal layer 20 away from the metal oxide semiconductor layer 30, the transparent conductive layer 40 including multiple first electrodes 41, each of the first electrodes 41 being electrically connected to one of the first electrode conductor portions 311 through a via hole. Respective first electrode conductor portions 311 in any two adjacent ones of the transparent active layers 31 in the first direction X are staggered.

It should be noted that the structure of the display panel according to Example 2 of the present disclosure is similar to that of the display panel according to Example 1 of the present disclosure, and details of same parts are not described in Example 2 of the present disclosure.

In one or more embodiments of the present disclosure, the second electrode conductor portion 313 in the transparent active layer 31 is electrically connected to the data line 21 through the second electrode connection hole H2. The second electrode conductor portion 313 in at least one of the transparent active layers 31 and the second electrode conductor portion 313 in another one of the transparent active layers 31 are joined, and each of two joined ones of the second electrode conductor portions 313 correspond to one of the second electrode connection holes H2.

In the display panel according to one or more embodiments of the present disclosure, since The second electrode conductor portion 313 in at least one of the transparent active layers 31 and the second electrode conductor portion 313 in another one of the transparent active layers 31 are joined, it is enabled that each of two joined ones of the second electrode conductor portions 313 correspond to one of the second electrode connection holes H2, that is, each of two joined ones of the second electrode conductor portions 313 can be electrically connected to the data line 21 through one of the second electrode connection holes H2, thereby reducing the number of the second connection holes, simplifying the manufacturing process of the display panel, reducing the production cost, and further improving the product yield.

In one or more embodiments of the present disclosure, two of the transparent active layers 31 respectively corresponding to two of the second electrode conductor portions 313 which are joined are in an integrated structure, and the two of the transparent active layers 31 are provided axisymmetrically.

In the display panel according to one or more embodiments of the present disclosure, since the two of the transparent active layers 31 respectively corresponding to two of the second electrode conductor portions 313 which are joined are in an integrated structure, the number of independent patterns in the metal oxide semiconductor layer 30 can be reduced, and the difficulty in forming the second electrode conductor portions 313 by a conductor forming process can be reduced. Further, since the two transparent active layers 31 are provided axisymmetrically, the layout design difficulty can be further reduced, and the production process can be simplified. Optionally, the two of the transparent active layers 31 respectively corresponding to two of the second electrode conductor portions 313 which are joined are disposed successively in the second direction Y.

In one or more embodiments of the present disclosure, two of the first electrodes 41 respectively corresponding to the two of the transparent active layers 31 are provided axisymmetrically.

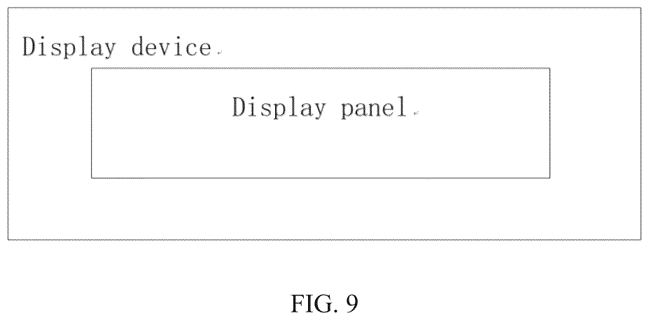

According to some embodiments of the present disclosure, as shown in FIG. 9, a display device includes a housing and any one of above-mentioned display panels. The housing has an accommodation space in which the display panel is disposed.

In summary, according to one or more embodiments of the present disclosure, a display panel has a display area AA, a part of the display panel in the display area AA including a substrate; a first metal layer disposed on a side of the substrate, the first metal layer including multiple data lines arranged at intervals in a first direction; a metal oxide semiconductor layer disposed between the substrate and the first metal layer, the metal oxide semiconductor layer including multiple transparent active layers, the transparent active layers including respective first electrode conductor portions, an orthographic projection of each of the first electrode conductor portions on the substrate being between two adjacent ones of the data lines; and a transparent conductive layer disposed on a side of the first metal layer away from the metal oxide semiconductor layer, the transparent conductive layer including multiple first electrodes, each of the first electrodes being electrically connected to one of the first electrode conductor portions through a via hole, respective first electrode conductor portions in any two adjacent ones of the transparent active layers in the first direction being staggered. In the display panel according to the present disclosure, the two first electrode conductor portions are provided in a staggered manner, thereby improving yield of the display panel while ensuring high resolution of the display panel.

Some embodiments of the present disclosure have been described in detail above. The description of the above embodiments merely aims to help to understand the present disclosure. Many modifications or equivalent substitutions with respect to the embodiments may occur to those of ordinary skill in the art based on the present disclosure. Thus, these modifications or equivalent substitutions shall fall within the scope of the present disclosure.

What is claimed is:

1. A display panel, having a display area, wherein in the display area the display panel comprises:
a substrate;
a first metal layer disposed on a side of the substrate, the first metal layer comprising a plurality of data lines arranged at intervals in a first direction;
a metal oxide semiconductor layer disposed between the substrate and the first metal layer, the metal oxide semiconductor layer comprising a plurality of transparent active layers, the transparent active layers respectively comprising a plurality of first electrode conductor portions, an orthographic projection of each of the first electrode conductor portions on the substrate being between respective orthographic projections of two adjacent ones of the data lines on the substrate; and
a transparent conductive layer disposed on a side of the first metal layer away from the metal oxide semiconductor layer, the transparent conductive layer comprising a plurality of first electrodes, each of the first electrodes being electrically connected to one of the first electrode conductor portions by a via hole connection,
wherein two of the first electrode conductor portions respectively in any two adjacent ones of the transparent active layers in the first direction are staggered.

2. The display panel according to claim 1, wherein in the display area the display panel further comprises:
a second metal layer disposed between the metal oxide semiconductor layer and the first metal layer, the second metal layer comprising a plurality of gate lines arranged at intervals in a second direction intersecting the first direction,
wherein the two of the first electrode conductor portions are disposed respectively on opposite sides of one of the gate lines.

3. The display panel according to claim 2, wherein an end of each of the two of the first electrode conductor portions away from the one of the gate lines is spaced from the one of the gate lines by a first distance;
every two adjacent ones of the gate lines are spaced by a second distance; and
the first distance is less than half of the second distance.

4. The display panel according to claim 2, wherein the transparent active layers further respectively comprise a plurality of channels and a plurality of second electrode conductor portions;
in each of the transparent active layers, one of the first electrode conductor portions and one of the second electrode conductor portions are arranged respectively on opposite sides of one of the channels;
an orthographic projection of each of the channels on the substrate is overlapped by an orthographic projection of one of the gate lines on the substrate;
an orthographic projection of each of the second electrode conductor portions on the substrate is at least partially overlapped by an orthographic projection of one of the data lines on the substrate; and
each of the second electrode conductor portions is electrically connected to one of the data lines by a via hole connection.

5. The display panel according to claim 4, wherein in the display area the display panel is provided with a plurality of second electrode connection holes respectively corresponding to the second electrode conductor portions, and each of the second electrode conductor portions is electrically connected to one of the data lines through one of the second electrode connection holes; and
the second electrode conductor portions respectively in the transparent active layers are spaced from each other.

6. The display panel according to claim 4, wherein in the display area the display panel is provided with a plurality of second electrode connection holes, and each of the second electrode conductor portions is electrically connected to one of the data lines through one of the second electrode connection holes; and
at least one pair of the second electrode conductor portions respectively in two of the transparent active layers are joined, and every two of the second electrode conductor portions that are joined are electrically connected to one of the data lines through one of the second electrode connection holes.

7. The display panel according to claim 6, wherein two of the transparent active layers respectively corresponding to the every two of the second electrode conductor portions that are joined are integrated and axisymmetric.

8. The display panel according to claim 4, wherein each of the first electrodes is electrically connected to one of the first electrode conductor portions through a first electrode connection hole, and comprises a first portion covering at least part of one of the channels and a second portion covering the first electrode connection hole; and
a maximum width of the second portion in the first direction is greater than a maximum width of the first portion in the first direction.

9. The display panel according to claim 4, wherein in the display area the display panel comprises a plurality of metal oxide thin film transistors, each of the metal oxide thin film transistors comprising one of the transparent active layers, a first gate, one of the first electrodes, and a second electrode; and
the second electrode is part of one of the data lines and is electrically connected to one of the second electrode conductor portions by a via hole connection, and the first gate is part of one of the gate lines.

10. The display panel according to claim 9, wherein in the display area the display panel further comprises a third metal layer disposed on a side of the metal oxide semiconductor layer close to the substrate; and
each of the metal oxide thin film transistors further comprises a second gate in the third metal layer, and an orthographic projection of the second gate on the substrate is overlapped by the orthographic projection of one of the channels on the substrate.

11. A display device, comprising a housing and a display panel disposed in the housing, the display panel having a display area,
wherein in the display area the display panel comprises:
a substrate;
a first metal layer disposed on a side of the substrate, the first metal layer comprising a plurality of data lines arranged at intervals in a first direction;
a metal oxide semiconductor layer disposed between the substrate and the first metal layer, the metal oxide semiconductor layer comprising a plurality of transparent active layers, the transparent active layers respectively comprising a plurality of first electrode conductor portions, an orthographic projection of each of the first electrode conductor portions on the substrate being between respective orthographic projections of two adjacent ones of the data lines on the substrate; and
a transparent conductive layer disposed on a side of the first metal layer away from the metal oxide semiconductor layer, the transparent conductive layer comprising a plurality of first electrodes, each of the first electrodes being electrically connected to one of the first electrode conductor portions by a via hole connection,
wherein two of the first electrode conductor portions respectively in any two adjacent ones of the transparent active layers in the first direction are staggered.

12. The display device according to claim 11, wherein in the display area the display panel further comprises:
a second metal layer disposed between the metal oxide semiconductor layer and the first metal layer, the second metal layer comprising a plurality of gate lines arranged at intervals in a second direction intersecting the first direction,
wherein the two of the first electrode conductor portions are disposed respectively on opposite sides of one of the gate lines.

13. The display device according to claim 12, wherein an end of each of the two of the first electrode conductor portions away from the one of the gate lines is spaced from the one of the gate lines by a first distance;
every two adjacent ones of the gate lines are spaced by a second distance; and
the first distance is less than half of the second distance.

14. The display device according to claim 12, wherein the transparent active layers further respectively comprise a plurality of channels and a plurality of second electrode conductor portions;
in each of the transparent active layers, one of the first electrode conductor portions and one of the second electrode conductor portions are arranged respectively on opposite sides of one of the channels;
an orthographic projection of each of the channels on the substrate is overlapped by an orthographic projection of one of the gate lines on the substrate;
an orthographic projection of each of the second electrode conductor portions on the substrate is at least partially overlapped by an orthographic projection of one of the data lines on the substrate; and
each of the second electrode conductor portions is electrically connected to one of the data lines by a via hole connection.

15. The display device according to claim 14, wherein in the display area the display panel is provided with a plurality of second electrode connection holes respectively corresponding to the second electrode conductor portions, and each of the second electrode conductor portions is electrically connected to one of the data lines through one of the second electrode connection holes; and
the second electrode conductor portions respectively in the transparent active layers are spaced from each other.

16. The display device according to claim 14, wherein in the display area the display panel is provided with a plurality of second electrode connection holes, and each of the second electrode conductor portions is electrically connected to one of the data lines through one of the second electrode connection holes; and
at least one pair of the second electrode conductor portions respectively in two of the transparent active layers are joined, and every two of the second electrode conductor portions that are joined are electrically connected to one of the data lines through one of the second electrode connection holes.

17. The display device according to claim 16, wherein two of the transparent active layers respectively corresponding to the every two of the second electrode conductor portions that are joined are integrated and axisymmetric.

18. The display device according to claim 14, wherein each of the first electrodes is electrically connected to one of the first electrode conductor portions through a first electrode connection hole, and comprises a first portion covering at least part of one of the channels and a second portion covering the first electrode connection hole; and
a maximum width of the second portion in the first direction is greater than a maximum width of the first portion in the first direction.

19. The display device according to claim 14, wherein in the display area the display panel comprises a plurality of metal oxide thin film transistors, each of the metal oxide thin film transistors comprising one of the transparent active layers, a first gate, one of the first electrodes, and a second electrode; and
the second electrode is part of one of the data lines and is electrically connected to one of the second electrode conductor portions by a via hole connection, and the first gate is part of one of the gate lines.

20. The display device according to claim 19, wherein in the display area the display panel further comprises a third metal layer disposed on a side of the metal oxide semiconductor layer close to the substrate; and
each of the metal oxide thin film transistors further comprises a second gate in the third metal layer, and an orthographic projection of the second gate on the substrate is overlapped by the orthographic projection of one of the channels on the substrate.
